(19) United States
(12) Patent Application Publication
(10) Pub. No.: US 2023/0298929 A1
(43) Pub. Date: Sep. 21, 2023

(54) THIN SHADOW RING FOR LOW-TILT TRENCH ETCHING

(71) Applicant: LAM RESEARCH CORPORATION, Fremont, CA (US)

(72) Inventors: David SETTON, Danville, CA (US); Ambarish CHHATRE, Danville, CA (US); Justin Charles CANNIFF, Santa Clara, CA (US); Dan MAROHL, San Jose, CA (US); Craig ROSSLEE, San Jose, CA (US)

(21) Appl. No.: 18/017,208

(22) PCT Filed: Jul. 30, 2021
(86) PCT No.: PCT/US2021/043873

§ 371 Date: Jan. 20, 2023

Related U.S. Application Data
(60) Provisional application No. 63/068,677, filed on Aug. 21, 2020.
(60) Provisional application No. 63/059,936, filed on Jul. 31, 2020.

(51) Int. Cl. H01L 21/687; H01L 21/67; H01J 37/32

(52) U.S. Cl. CPC H01L 21/68742; H01L 21/67069; H01L 21/68785; H01J 37/32715; H01J 2237/3341

(57) ABSTRACT

A thin shadow ring for a substrate processing system includes an annular body having an inner diameter and an outer diameter. The inner diameter and the outer diameter define a cross-sectional width of the annular body between the inner diameter and the outer diameter. At least two tabs extend radially outward from the annular body. The cross-sectional width of the annular body between the inner diameter and the outer diameter is less than 1.0 inch.

### CROSS-REFERENCE TO RELATED APPLICATIONS

This application claims the benefit of U.S. Provisional Application No. 63/059,936, filed on Jul. 31, 2020 and U.S. Provisional Application No. 63/068,677, filed on Aug. 21, 2020. The entire disclosures of the applications referenced above are incorporated herein by reference.

### FIELD

The present disclosure relates to a shadow ring for semiconductor processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, etch processes and deposition processes may be performed within a processing chamber. The substrate is disposed in the processing chamber on a substrate support such as an electrostatic chuck (ESC) or a pedestal. Process gases are introduced and plasma is struck in the processing chamber.

Some substrate processing systems may be configured to perform deep silicon etch (DSiE) processing and/or a rapid alternating process (RAP), which includes rapidly switching between etch and deposition processes. For example, a RAP may be used in microelectromechanical system (MEMS) etching, DSiE processing, etc.

### SUMMARY

A thin shadow ring for a substrate processing system includes an annular body having an inner diameter and an outer diameter. The inner diameter and the outer diameter define a cross-sectional width of the annular body between the inner diameter and the outer diameter. At least two tabs extend radially outward from the annular body. The cross-sectional width of the annular body between the inner diameter and the outer diameter is less than 1.0 inch.

In other features, the cross-sectional width of the annular body between the inner diameter and the outer diameter is less than 0.5 inches. The cross-sectional width of the annular body between the inner diameter and the outer diameter is less than 0.25 inches. The at least two tabs includes at least three tabs extending radially outward from the annular body. At least one of the two tabs includes an opening extending through the tab. A lower surface of at least one of the two tabs includes a recess configured to receive a lift pin. An upper surface of the annular body is sloped.

In other features, a substrate support includes the thin shadow ring and further includes at least two lift pins configured to engage with the at least two tabs of the thin shadow ring to raise and lower the thin shadow ring. At least one of the two tabs of the thin shadow ring extends over an outer edge of the substrate support. The substrate support is configured to support a substrate having an outer diameter and an inner diameter of the annular body is less than the outer diameter of the substrate. An upper surface of the substrate support defines a recess configured to receive a substrate and a portion of the annular body of the thin shadow ring overlaps the recess.

In other features, an acute angle is defined at the inner diameter of the annular body between an upper surface of the annular body and a lower surface of the annular body. The upper surface and the lower surface form a sharp corner at an inner edge of the shadow ring, the inner edge is rounded, the inner edge has a radius between 0.0 and 0.025 inches, the acute angle is between 1 and 35 degrees, or a thickness of the inner edge is less than 0.01 inches.

A substrate support for a substrate processing system configured to perform deep-trench etching and shallow-trench etching includes a recess defined in an upper surface of the substrate support. The recess is configured to receive a substrate. A shadow ring includes an annular body having an inner diameter and an outer diameter. The inner diameter and the outer diameter define a cross-sectional width of the annular body between the inner diameter and the outer diameter. At least two tabs extend radially outward from the annular body over an outer edge of the substrate support. The cross-sectional width of the annular body between the inner diameter and the outer diameter is less than 1.0 inches and the inner diameter of the annular body is less than an outer diameter of the recess. A lifting pin is aligned with one of the at least two tabs of the shadow ring. The lifting pin is configured to move the shadow ring between a lowered position and a raised position.

In other features, the cross-sectional width of the annular body between the inner diameter and the outer diameter is less than 0.5 inches. The cross-sectional width of the annular body between the inner diameter and the outer diameter is less than 0.25 inches. The shadow ring includes at least three tabs. At least one of the two tabs includes an opening extending through the tab. An upper surface of the annular body is sloped. The inner diameter of the annular body is less than an outer diameter of the substrate.

In other features, a substrate processing system includes the substrate support. The substrate processing system is configured to actuate the lifting pin to raise the shadow ring to the raised position during a shallow-trench etching process and lower the shadow ring to the lowered position during a deep-trench etching process.

In other features, an acute angle is defined at the inner diameter of the annular body between an upper surface of the annular body and a lower surface of the annular body. The upper surface and the lower surface form a sharp corner at an inner edge of the shadow ring, the inner edge is rounded, the inner edge has a radius between 0.0 and 0.025 inches, the acute angle is between 1 and 35 degrees, or a thickness of the inner edge is less than 0.01 inches.

A shadow ring for a substrate processing system includes an annular body, an inner diameter, an outer diameter, a lower surface, and an upper surface defined between the inner diameter and the outer diameter. The upper surface includes an outer portion and an inner portion, the inner portion is sloped, the inner portion of the upper surface meets the lower surface of the shadow ring to define an inner edge at the inner diameter of the shadow ring, and an acute angle is defined at the inner edge between the inner portion and the lower surface.

In other features, the inner portion of the upper surface and the lower surface form a sharp corner at the inner edge. The inner edge is rounded. The inner edge has a radius between 0.0 and 0.025 inches. The acute angle is between 1 and 35 degrees. A thickness of the inner edge is less than 0.01 inches. The outer portion of the upper surface is horizontal. The inner portion is flat.

In other features, the inner diameter and the outer diameter define a cross-sectional width of the annular body between the inner diameter and the outer diameter, and the cross-sectional width of the annular body between the inner diameter and the outer diameter is less than 1.0 inch. The cross-sectional width of the annular body between the inner diameter and the outer diameter is less than 0.5 inches. The cross-sectional width of the annular body between the inner diameter and the outer diameter is less than 0.25 inches.

In other features, the shadow ring further includes at least two tabs extending radially outward from the annular body. A substrate support includes the shadow ring and further includes at least two lift pins configured to engage with the at least two tabs of the shadow ring to raise and lower the shadow ring. At least one of the two tabs of the shadow ring extends over an outer edge of the substrate support. The substrate support is configured to support a substrate having an outer diameter, and wherein an inner diameter of the annular body is less than the outer diameter of the substrate. An upper surface of the substrate support defines a recess configured to receive a substrate, and wherein the inner edge of the shadow ring overlaps the recess.

A substrate support for a substrate processing system is configured to perform deep-trench etching and shallow-trench etching. The substrate support includes a recess that is defined in an upper surface of the substrate support and is configured to receive a substrate. The substrate support further includes a shadow ring including an annular body having an inner diameter, an outer diameter, a lower surface, and an upper surface defined between the inner diameter and the outer diameter. The upper surface includes an outer portion and an inner portion, the inner portion is sloped, the inner portion of the upper surface meets the lower surface of the shadow ring to define an inner edge at the inner diameter of the shadow ring, and an acute angle is defined at the inner edge between the inner portion and the lower surface. The inner diameter and the outer diameter define a cross-sectional width of the annular body between the inner diameter and the outer diameter, the cross-sectional width of the annular body between the inner diameter and the outer diameter is less than 1.0 inches, and the inner diameter of the annular body is less than an outer diameter of the recess.

In other features, the inner portion of the upper surface and the lower surface form a sharp corner at the inner edge. The inner edge is rounded. The inner edge has a radius between 0.0 and 0.025 inches. The acute angle is between 1 and 35 degrees. A thickness of the inner edge is less than 0.01 inches. The cross-sectional width of the annular body between the inner diameter and the outer diameter is less than 0.5 inches. The cross-sectional width of the annular body between the inner diameter and the outer diameter is less than 0.25 inches.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of a substrate processing system including an example shadow ring according to the present disclosure;

FIG. 1B shows an example shadow ring in a lowered position according to some embodiments of the present disclosure;

FIG. 1C shows an example shadow ring in a raised position according to some embodiments of the present disclosure;

FIG. 2A shows an isometric view of an example shadow ring according to some embodiments of the present disclosure;

FIGS. 2B and 2C show plan views of an example shadow ring according to some embodiments of the present disclosure;

FIG. 2D shows a bottom view of an example shadow ring according to some embodiments of the present disclosure;

FIGS. 3A, 3B, 3C, 3D, and 3E show side views of example thin shadow rings having a modified inner diameter according to some embodiments of the present disclosure;

FIGS. 4A, 4B, 4C, 4D, and 4E show side views of example shadow rings having a modified inner diameter according to some embodiments of the present disclosure; and

FIG. 5 illustrates effects of the modified inner diameter on edge tilt symmetry according to some embodiments of the present disclosure.

In the drawings, reference numbers may be reused to identify similar and/or identical elements.

### DETAILED DESCRIPTION

Some substrate supports (e.g., substrate supports in substrate processing systems configured to perform deep-trench etching processes) may include a shadow ring. During etching processes, a substrate is arranged on the substrate support. Bevels at outer edges of the substrate may be exposed to etching. The shadow ring may be used to protect the bevels of the substrate from etching. For example, the shadow ring may be raised to facilitate transfer of the substrate to the substrate support and then lowered. An inner diameter of the shadow ring overlaps the outer edge of the substrate to protect the bevels from being etched during deep-trench etching processes.

The shadow ring may disrupt flow of process gases above the substrate and cause bending of the plasma sheath, which may induce tilting in etched trenches. While deep-trench etching processes typically do not have strict tilt requirements, other etching processes (e.g., shallow-trench etching processes) may have strict tilt requirements. Conversely, shallow-trench etching processes may not require bevel protection. Accordingly, in processing chambers configured to perform both deep-trench and shallow-trench etching, the shadow ring may be lowered during deep-trench etching processes (to protect the bevels of the substrate) and raised during shallow-trench etching or other processes (to minimize tilt).

While raising the shadow ring reduces the disruption of process gas flow and bending of the plasma sheath, the presence of the shadow ring still induces tilting. For example, a typical shadow ring may have a uniform cross-section width between 2.0 and 4.0 inches (between 50.8 and 101.6 mm). Accordingly, the shadow ring disrupts gas flow from a showerhead positioned above the substrate support. When in a lowered position, the shadow ring may induce tilt by causing the plasma sheath to bend. Conversely, when in a raised position, the shadow ring may induce tilt by disrupting process gas flow.

A shadow ring according to the present disclosure is configured to minimize plasma sheath bending and disruption of process gas flow. In some embodiments, the width of the shadow ring (i.e., a width of a cross-section of the shadow ring) is reduced along some portions of its annular body to minimize disruption of process gas flow when in the raised position while still protecting the bevels of the substrate when in the lowered position.

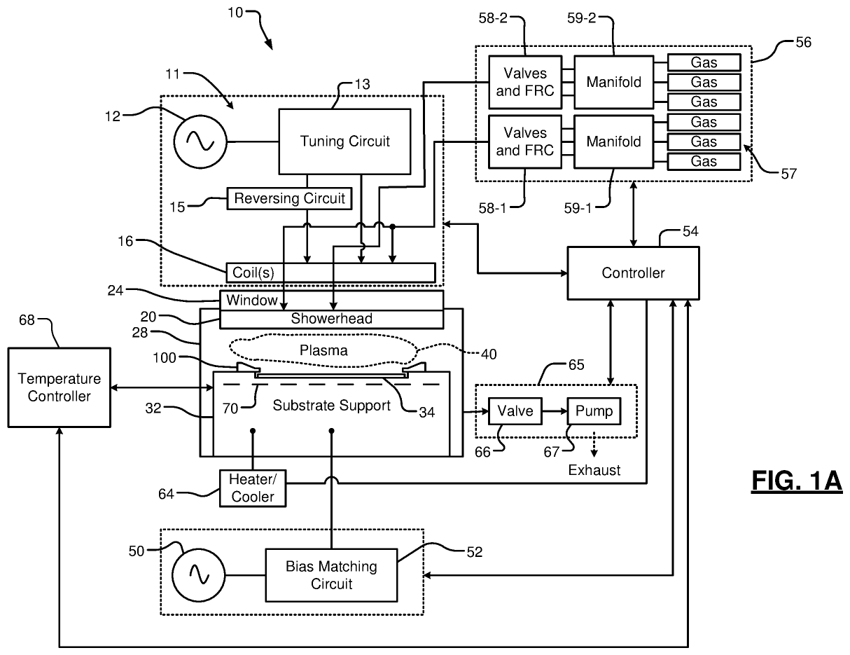

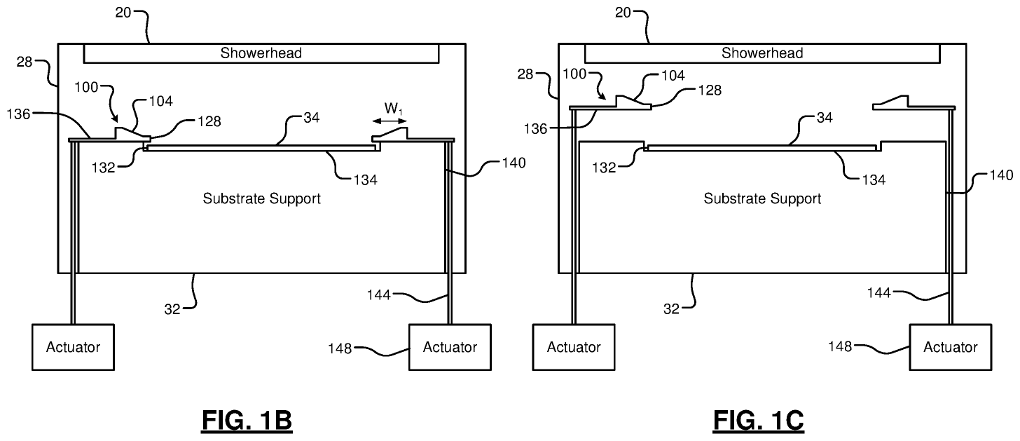

Referring now to FIG. 1A, an example of a substrate processing system 10 according to the present disclosure is shown. The substrate processing system 10 includes a coil driving circuit 11. As shown, the coil driving circuit 11 includes an RF source 12 and a tuning circuit 13. The tuning circuit 13 may be directly connected to one or more inductive transformer coupled plasma (TCP) coils 16. Alternatively, the tuning circuit 13 may be connected by an optional reversing circuit 15 to one or more of the coils 16. The tuning circuit 13 tunes an output of the RF source 12 to a desired frequency and/or a desired phase, matches an impedance of the coils 16 and splits power between the TCP coils 16. The reversing circuit 15 is used to selectively switch the polarity of current through one or more of the TCP coils 16. In some examples, the coil driving circuit 11 implements a transformer coupled capacitive tuning (TCCT) match network to drive the TCP coils 16.

A gas distribution device (e.g., a showerhead 20 defining one or more plenums therein) is arranged between a dielectric window 24 and a processing chamber 28. For example, the dielectric window 24 comprises ceramic. In some embodiments, the showerhead 20 comprises ceramic or another dielectric material. The processing chamber 28 further comprises a substrate support (or pedestal) 32. The substrate support 32 may include an electrostatic chuck (ESC), or a mechanical chuck or other type of chuck.

Process gas is supplied to the processing chamber 28 via the showerhead 20 and plasma 40 is generated inside of the processing chamber 28. For example, an RF signal is transmitted from the TCP coils through the dielectric window 24 into the interior of the processing chamber 28. The RF signal excites gas molecules within the processing chamber 28 to generate plasma 40. The plasma 40 etches an exposed surface of the substrate 34. An RF source 50 and a bias matching circuit 52 may be used to bias the substrate support 32 during operation to control ion energy.

A gas delivery system 56 may be used to supply a process gas mixture to the processing chamber 28. The gas delivery system 56 may include process and inert gas sources 57 (e.g., including deposition gases, etch gases, carrier gases, inert gases, etc.), gas metering systems 58-1 and 58-1 such as valves and flow ratio controllers (e.g., mass flow controllers (MFCs)), and respective manifolds 59-1 and 59-2. For example, the gas metering system 58-1 and the manifold 59-1 may be arranged to provide etch gas mixtures to the processing chamber 28 during etching while the gas metering system 58-2 and the manifold 59-2 may be arranged to provide deposition gas mixtures to the processing chamber 28 during deposition. For example, the etch and deposition gas mixtures may be provided to the plenums of the showerhead 20 through the coil 16 and via respective passages in the dielectric window 24. A heater/cooler 64 may be used to heat/cool the substrate support 32 to a predetermined temperature. An exhaust system 65 includes a valve 66 and pump 67 to remove reactants from the processing chamber 28 by purging or evacuation.

A controller 54 may be used to control the etching process. The controller 54 monitors system parameters and controls delivery of the gas mixture, striking, maintaining and extinguishing the plasma, removal of reactants, and so on. Additionally, the controller 54 may control various aspects of the coil driving circuit 11, the RF source 50, and the bias matching circuit 52, etc. In some embodiments, the substrate support 32 is temperature-tunable. In certain embodiments, a temperature controller 68 may be connected to a plurality of heating elements 70, such as thermal control elements (TCEs), arranged in the substrate support 32. The temperature controller 68 may be used to control the plurality of heating elements 70 to control a temperature of the substrate support 32 and the substrate 34.

Referring now to FIGS. 1B and 1C and with continued reference to FIG. 1A, the substrate support 32 includes a thin shadow ring 100 according to some embodiments of the present disclosure. The thin shadow ring 100 has a cross-section width W₁ that is significantly reduced relative to conventional shadow rings. In some embodiments, the thin shadow ring 100 may be comprised of a ceramic material, such as alumina (e.g., Al₂O₃). In some embodiments, the thin shadow ring 100 is coated in a plasma-resistant material such as yttrium oxide. As shown in FIGS. 1B and 1C, the thin shadow ring 100, according to some embodiments, is configured to be moved between a lowered position (as shown in FIG. 1B) and a raised position (as shown in FIG. 1C).

The width W₁ of the body 104 of the thin shadow ring 100 according to some embodiments of the present disclosure may be less than about 1.0 inch (25.4 mm). In some embodiments, the width W₁ is between about 0.20 and 0.5 inches (5.08 and 12.7 mm). Accordingly, an upper surface area of the body 104 of the thin shadow ring 100 facing the showerhead 20 is significantly reduced. The reduction of width minimizes the disruption of process gas flow between the showerhead 20 and the substrate 34 when the thin shadow ring 100 is in the raised position (for example, as shown in FIG. 1C). In the lowered position, an inner edge 128 of the thin shadow ring 100 overlaps the substrate 34 and protects an edge 132 of the substrate 34 from etching (for example, as shown in FIG. 1B). In certain embodiments, the thin shadow ring 100 overlaps about 1.0-2.0 mm of the edge 132 of the substrate 34. In other words, if the substrate 34 has an outer diameter D_{sub}, an inner diameter of the annular body 104 of the thin shadow ring 100 is less than D_{sub}. An upper surface of the substrate support 32 may define a recess 134 configured to receive the substrate 34 and the thin shadow ring 100 overlaps a portion of the recess 134. In some embodiments, an upper surface of the body 104 of the thin shadow ring 100 is sloped to facilitate flow of process gases around the thin shadow ring 100 when in the raised position.

In some embodiments, the thin shadow ring 100 includes arms or tabs 136 extending radially outward from the body 104 of the thin shadow ring 100. In some embodiments, the thin shadow ring 100 includes three of the tabs 136. In some embodiments, the thin shadow ring 100 includes less than (e.g., two) or more than three of the tabs 136. The tabs 136 extend over an outer edge 140 of the substrate support 32. In other words, an outer diameter defined by the tabs 136 may be greater than the outer diameter of the substrate support 32. In some embodiments, the tabs 136 extend over the substrate support 32 and are aligned with lift pins 144. In this manner, the tabs 136 can be engaged by one or more of the lift pins 144 to raise and lower the thin shadow ring 100. Actuators 148 (e.g., linear actuators responsive to the controller 54) raise and lower the lift pins 144 to raise and lower the thin shadow ring 100.

In some embodiments, a vertical thickness of the tabs 136 is less than (e.g., less than 50%, 60%, 70%, 80%, 90% of) a vertical thickness of the body 104. In other embodiments, the vertical thickness of the tabs 136 may be closer to (e.g., within 5%, 10% of) the vertical thickness of the body 104.

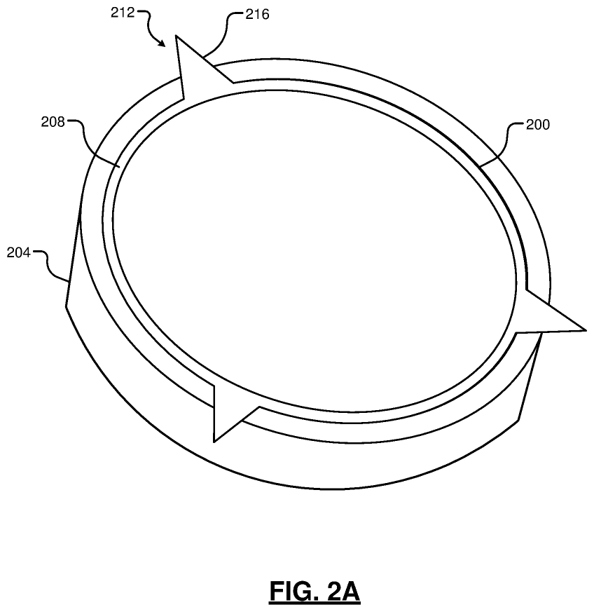

Referring now to FIGS. 2A, 2B, and 2C, example embodiments of a thin shadow ring 200 according to the present disclosure are shown. In FIG. 2A, the thin shadow ring 200 is shown in an isometric view arranged on a substrate support 204. FIGS. 2B and 2C show plan views of the thin shadow ring 200. The thin shadow ring 200 includes an annular body 208 and a plurality of tabs 212 (e.g., three of the tabs 212) extending radially outward from the body 208. As shown in FIG. 2A, the tabs 212 extend over an outer diameter or perimeter of the substrate support 204.

Although shown as having a generally triangular shape, the tabs 212 may have other suitable shapes (e.g., rectangular, semi-circular, etc.). A quantity of the tabs 212 and a surface area of an upper surface 216 of the tabs 212 is minimized to minimize disruption to process gas flow around the tabs 212. In some embodiments, as shown in FIGS. 2A and 2B, the upper surface 216 of the tabs 212 is continuous. In some embodiments, as shown in FIG. 2C, the upper surface 216 includes openings 220 passing through the tabs 212. In some embodiments, a shadow ring may have one or more tabs with continuous surfaces and one or more tabs with openings 220 (not shown). In FIG. 2C, each of the tabs 212 may include an outer rim 224 defining the openings 220. The openings 220 allow process gases flowing downward from the showerhead 20 to pass through the tabs 212. Accordingly, the openings 220 reduce disruption of process gas flow surrounding the tabs 212 and minimize tilt at locations of the substrate 34 corresponding to the locations of the tabs 212.

FIG. 2D is a bottom view of the thin shadow ring 200 showing a lower surface 228 of the tabs 212 in FIG. 2C. In some embodiments, the lower surface 228 includes a recess 232 arranged to receive a respective one of the lift pins 120 (shown in FIGS. 1B and 1C). In some embodiments, the recess 232 facilitates alignment of the thin shadow ring 200 with the lift pins 120 and the substrate support 204.

Some shadow rings have a squared-off inner diameter or edge (i.e., a square profile) as shown in FIGS. 1B and 1C. As shown in FIGS. 1B and 1C, the inner edge 128 of the thin shadow ring 100 is substantially vertical. For example only, a height or thickness of the inner edge 128 is about 0.125 inches (3.175 mm) or greater. A square profile of an inner diameter of a shadow ring impacts a profile of the plasma sheath at the outer diameter or edge of the substrate. For example, the square profile may alter the plasma sheath and cause tilting in etched features. While the tilting may be minimal in some processes, the tilting is amplified in high aspect ratio etching processes and may cause trench sidewall damage.

In some embodiments of the present disclosure, the inner diameter of the shadow ring is modified to reduce the impact on the plasma sheath and minimize tilting. For example, the profile of the inner diameter is modified to have a sharp, radiused (i.e., rounded), or square profile with a reduced height as described below in more detail.

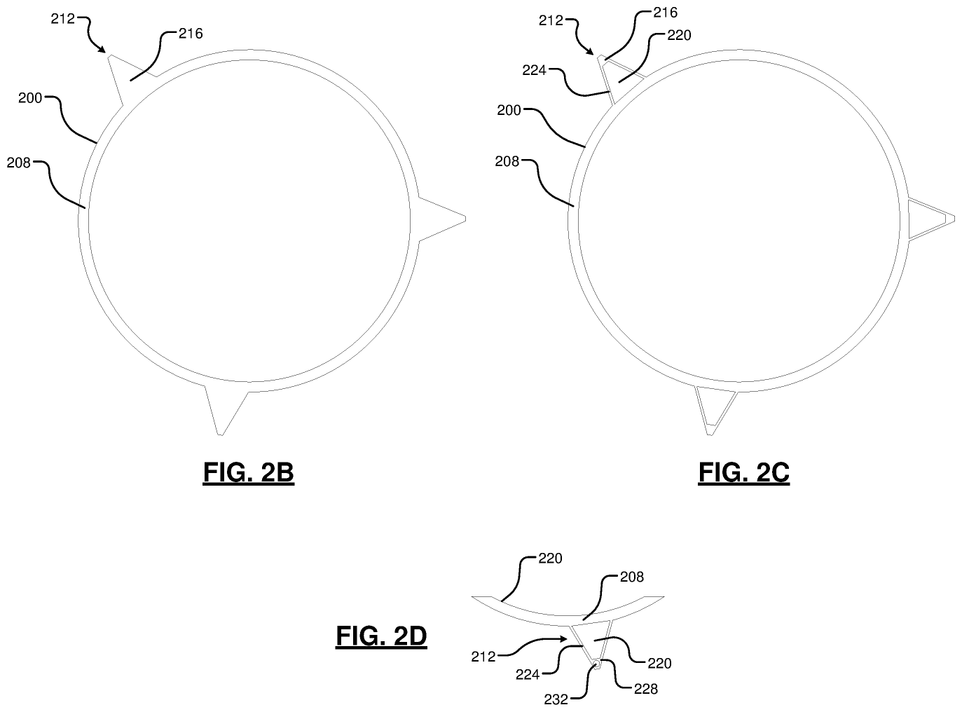

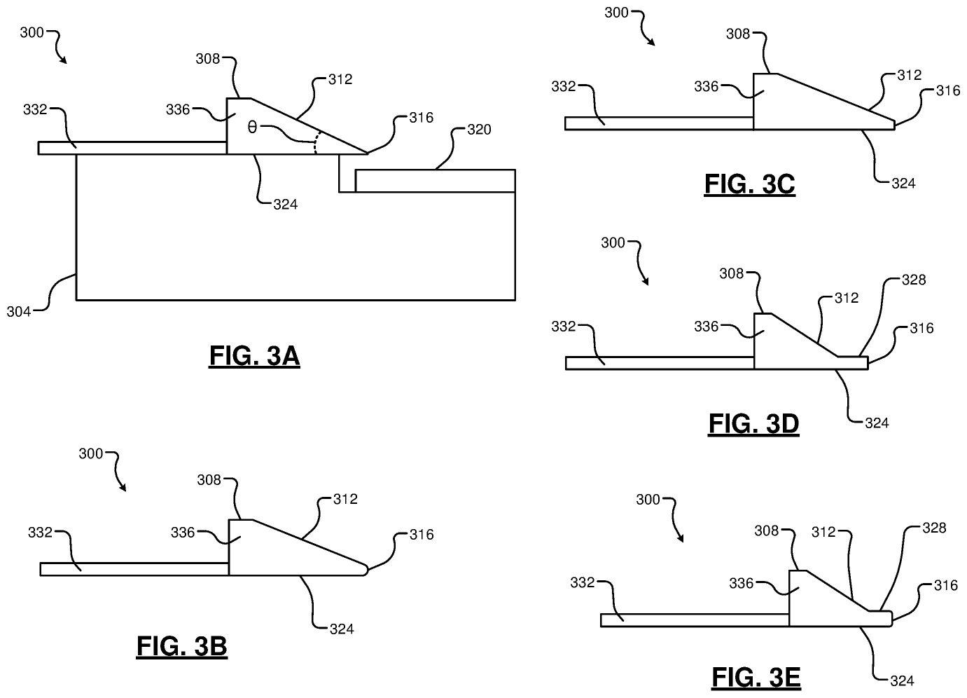

Referring now to FIGS. 3A, 3B, 3C, 3D, and 3E, cross-sections (i.e., side views) of an embodiment of a shadow ring 300 according to the present disclosure are shown. The shadow rings 300 correspond to a thin shadow ring having a reduced cross-section width as described above in FIGS. 1B, 1C, and 2A-2D. In FIG. 3A, the thin shadow ring 300 is shown arranged on a substrate support 304. For simplicity, the thin shadow ring 300 is shown without the substrate support 304 in FIGS. 3B, 3C, 3D, and 3E.

As shown in FIG. 3A, an upper surface of the thin shadow ring 300 includes an outer, generally horizontal portion 308 and an inner, sloped portion 312. Although shown as generally planar (i.e., flat), in some embodiments the sloped portion 312 may be convex or concave. An inner edge 316 of the thin shadow ring 300 extending over an outer diameter of a substrate 320 is “sharp.” In some embodiments, “sharp” may be defined as defining a sharp point or corner between the upper surface of the sloped portion 312 and a lower surface 324 of the shadow ring. In other embodiments, “sharp” may be defined as having a radius between about 0.0 and 0.025 inches (e.g., 0.0 and 0.635 mm). The upper surface of the sloped portion 312 meets the lower surface 324 of the shadow ring to define an acute angle θ. In other words, the acute angle is defined at an intersection between the sloped portion 312 and the lower surface 324. For example, the angle θ is between about 1 and 35 degrees. In an embodiment, the angle θ is approximately 20 degrees (e.g., 19-21 degrees).

As shown, a height or thickness of arms or tabs 332 extending from a body 336 of the thin shadow ring 300 is less than a height or thickness of the body 336. In other words, an upper surface of the arms 332 is stepped downward relative to an upper surface of the body 336. In other examples, the thickness of the arms 332 is about the same as the thickness of the body 336 (i.e., an upper surface of the arms 332 is coplanar with an upper surface of the body 336).

In another embodiment shown in FIG. 3B, the inner edge 316 of the thin shadow ring 300 has a radius between about 0.025 and 0.0625 inches (e.g., 0.635 and 1.5875 mm). Accordingly, a thickness of the inner edge 316 as shown in FIG. 3B is slightly greater than the thickness of the inner edge 316 as shown in FIG. 3A but still provides reduced impact on the plasma sheath relative to a square profile having a same or greater thickness.

In an embodiment shown in FIG. 3C, the inner edge 316 of the thin shadow ring 300 is generally square but has a reduced thickness (e.g., less than about 0.025 inches (0.635 mm)). In other words, although the inner edge 316 is generally square, the thickness of the inner edge 316 is significantly reduced relative to the thickness of the inner edge 128 (e.g., about 0.125 inches) described above. Accordingly, the generally square inner edge 316 according to FIG. 3C may be defined as “sharp.” In other words, a thickness of the inner edge 316 as shown in FIG. 3C is slightly greater than the thickness of the inner edge 316 as shown in FIG. 3A but still provides reduced impact on the plasma sheath relative to a square profile having a greater thickness.

In an embodiment shown in FIG. 3D, the sloped portion 312 transitions to an inner, generally horizontal shelf portion 328. A thickness of the shelf portion 328 is less than about 0.0625 inches (1.5875 mm). Accordingly, the inner edge 316 of the thin shadow ring 300 as shown in FIG. 3D has a thickness less than about 0.0625 inches (1.5875 mm). The inner edge 316 may be rounded (e.g., with a radius between about 0.025 and 0.0625 inches (e.g., 0.635 and 1.5875 mm) or may have a square profile. Accordingly, a rounded or generally square inner edge 316 according to FIG. 3D may be defined as “sharp.” In other words, a thickness of the inner edge 316 as shown in FIG. 3D is slightly greater than the thickness of the inner edge 316 as shown in FIG. 3A but still provides reduced impact on the plasma sheath relative to a square profile having a greater thickness. A length of the shelf portion 328 relative to the body 336 may vary.

In the embodiment shown in FIG. 3E, the sloped portion 312 transitions to an inner, generally horizontal shelf portion 328. A thickness of the shelf portion 328 is less than about 0.05 inches (1.27 mm). Accordingly, the inner edge 316 of the thin shadow ring 300 as shown in FIG. 3D has a thickness less than about 0.05 inches (1.27 mm). As shown, corners of the inner edge 316 are rounded. Accordingly, a rounded inner edge 316 according to FIG. 3E may be defined as “sharp.” In other words, a thickness of the inner edge 316 as shown in FIG. 3E is slightly greater than the thickness of the inner edge 316 as shown in FIG. 3A but still provides reduced impact on the plasma sheath relative to a round or square profile having a greater thickness. A length of the shelf portion 328 relative to the body 336 may vary.

Accordingly, the thickness of the thin shadow ring 300 at the inner edge 316 as shown in FIGS. 3A-3E is significantly reduced (e.g., in some embodiments, to about 0) and/or a shape of the profile of the inner edge 316 is modified to minimize the impact on the plasma sheath.

In some embodiments, an inner diameter of the thin shadow ring 300 is selected to provide an overlap of the substrate 320 of about 0.5 mm (e.g., an inner diameter of 11.771 inches (299 mm)). In other embodiments, the inner diameter of the thin shadow ring 300 is selected to provide an overlap of the substrate 320 of about 1.0 mm (e.g., an inner diameter of 11.732 inches (298 mm)) or 2.0 mm (e.g., an inner diameter of 11.654 inches (296 mm)). The profile of the inner edge 316 of the thin shadow ring 300 and the amount of overlap can be selected to optimize protection of the outer diameter of the substrate 320 and reduction of impact on the plasma sheath.

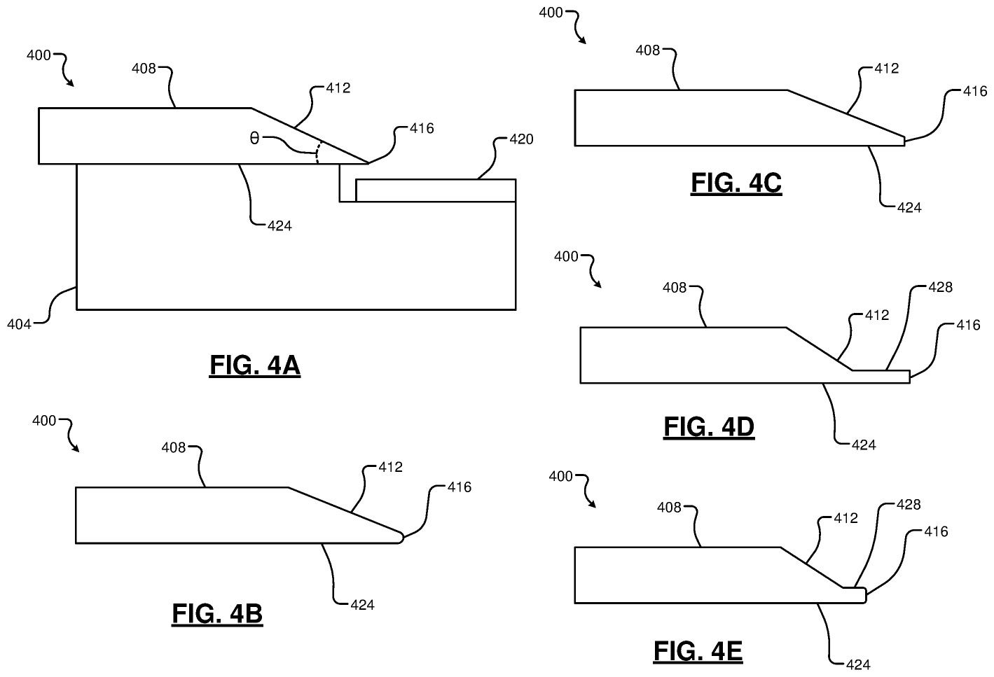

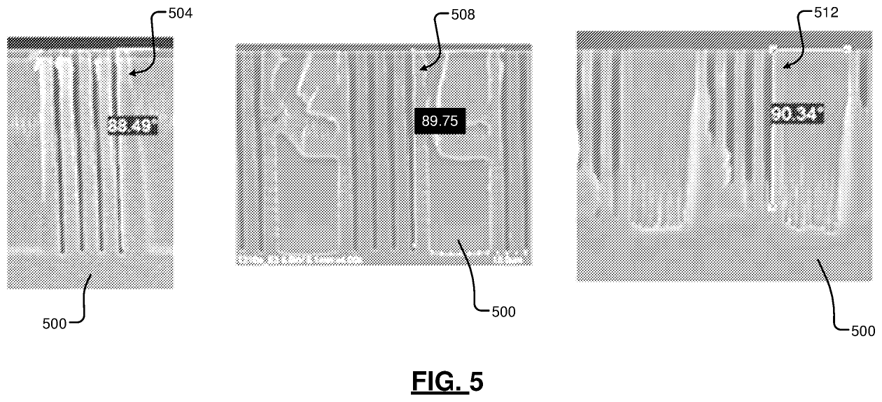

Referring now to FIGS. 4A, 4B, 4C, 4D, and 4E, cross-sections (i.e., side views) of a portion of another embodiment of a shadow ring 400 according to the principles of the present disclosure are shown. In FIG. 4A, the shadow ring 400 is shown arranged on a substrate support 404. For simplicity, the shadow ring 400 is shown without the substrate support 404 in FIGS. 4B, 4C, 4D, and 4E. In these embodiments, the shadow ring 400 does not have the reduced cross-sectional width of the shadow rings 300 described above. In other words, an outer diameter of the shadow ring 400 may extend over an outer edge 140 of the substrate support 32 shown in FIGS. 1B and 1C.

As shown in FIG. 4A, an upper surface of the shadow ring 400 includes an outer, generally horizontal portion 408 and an inner, sloped portion 412. Although shown as generally planar (i.e., flat), in some embodiments the sloped portion 412 may be convex or concave. An inner edge 416 of the shadow ring 400 extending over an outer diameter of a substrate 420 is “sharp” as defined above with respect to FIGS. 3A-3E. For example, “sharp” may be defined as defining a sharp point or corner between the upper surface of the sloped portion 412 and a lower surface 424 of the shadow ring, having a radius between about 0.0 and 0.025 inches (e.g., 0.0 and 0.635 mm), etc. The upper surface of the sloped portion 412 meets the lower surface 424 of the shadow ring to define an acute angle θ. In other words, the acute angle is defined at an intersection between the sloped portion 412 and the lower surface 424. For example, the angle θ is between about 1 and 35 degrees. In an embodiment, the angle θ is approximately 20 degrees (e.g., 19-21 degrees). Accordingly, the thickness of the shadow ring 400 at the inner edge 416 is significantly reduced (e.g., in some embodiments, to essentially 0 (less than about 0.01 inches)) to minimize the impact on the plasma sheath.

In another embodiment shown in FIG. 4B, the inner edge 416 of the shadow ring 400 has a radius between about 0.025 and 0.0625 inches (e.g., 0.635 and 1.5875 mm). Accordingly, a thickness of the inner edge 416 as shown in FIG. 4B is greater than the thickness of the inner edge 416 as shown in FIG. 4A but still provides reduced impact on the plasma sheath relative to a square profile having a same or greater thickness.

In an embodiment shown in FIG. 4C, the inner edge 416 of the shadow ring 400 is generally square but has a reduced thickness (e.g., less than about 0.025 inches (0.635 mm)). Accordingly, the inner edge 416 as shown in FIG. 4C may still provide reduced impact on the plasma sheath relative to a square profile having a greater thickness.

In an embodiment shown in FIG. 4D, the sloped portion 412 transitions to an inner, generally horizontal shelf portion 428. A thickness of the shelf portion 428 is less than about 0.0625 inches (1.5875 mm). Accordingly, the inner edge 416 of the shadow ring 400 as shown in FIG. 4D has a thickness less than about 0.0625 inches (1.5875 mm). The inner edge 416 may be rounded (e.g., with a radius between about 0.025 and 0.0625 inches (e.g., 0.635 and 1.5875 mm) or may have a square profile.

In an embodiment shown in FIG. 4E, the sloped portion 412 transitions to an inner, generally horizontal shelf portion 428. A thickness of the shelf portion 428 is less than about 0.05 inches (1.27 mm). Accordingly, the inner edge 416 of the shadow ring 400 as shown in FIG. 4D has a thickness less than about 0.05 inches (1.27 mm). As shown, corners of the inner edge 416 are rounded.

In some embodiments, an inner diameter of the shadow ring 400 is selected to provide an overlap of the substrate 420 of about 0.5 mm (e.g., an inner diameter of 11.771 inches (299 mm)). In other embodiments, the inner diameter of the shadow ring 400 is selected to provide an overlap of the substrate 420 of about 1.0 mm (e.g., an inner diameter of 11.732 inches (298 mm)) or 2.0 mm (e.g., an inner diameter of 11.654 inches (296 mm)). The profile of the inner edge 416 of the shadow ring 400 and the amount of overlap can be selected to optimize protection of the outer diameter of the substrate 420 and reduction of impact on the plasma sheath.

Referring now to FIG. 5, images of an edge of a substrate 500 show tilting of features at an edge of a substrate subsequent to performing etching using shadow rings having different inner diameters. Tilt refers to tilting of sidewalls of vertical features, such as trenches, relative to a desired (e.g., completely vertical, or 90 degrees) orientation. Feature tilt can be expressed as a degree of offset from 90 degrees (i.e., relative to a horizontal surface of the substrate). Tilt reduces performance of semiconductor devices and excessive tilt can reduce yield.

The shadow rings 300 and 400 described above reduce tilt at an edge of a semiconductor substrate. For example, edge tilt when using a shadow ring having a thicker squared-off inner diameter (i.e., without the reduced thickness described in FIG. 3A-3E or 4A-4E, such as a squared-off inner diameter having a thickness of about 0.125 inches or greater) is shown at 504. Edge tilt when using a shadow ring having a sharp or reduced thickness inner diameter (e.g., less than 0.05 inches, corresponding to the inner edge 316 or 416 shown in FIG. 3B or 4B, respectively) and a 1.0 mm overlap of the substrate 500 is shown at 508. In this example, edge tilt is improved relative to the edge tilt shown at 504 (e.g., from a measured sidewall angle of 88.49 degrees to 89.75 degrees, for a tilt improvement of about 1.26 degrees. In other words, he tilting effect is reduced and the features are now more perpendicular to the upper surface of the substrate).

Edge tilt when using a shadow ring having a sharp or reduced thickness inner diameter (e.g., less than 0.05 inches, corresponding to the inner edge 316 or 416 shown in FIG. 3B or 4B, respectively) and a 0.5 mm overlap of the substrate 500 is shown at 512. In this example, edge tilt is also improved relative to the edge tilt shown at 504 (e.g., from a measured sidewall angle of 88.49 degrees to 90.34 degrees, for a tilt improvement of 1.17 degrees). Further, decreasing the overlap from 1.0 mm to 0.5 mm decreases sidewall damage.

While the examples shown in FIG. 5 demonstrate tilt improvement for two shadow ring configurations according to the present disclosure, further reducing the thickness of the shadow ring at the inner diameter may further reduce tilt. The thickness of the inner diameter and the amount of overlap may be further adjusted to obtain desired tilt improvement results for different applications, processing chambers, and processes.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” Further, the phrase A, B, or C should be construed to mean a logical (A OR B OR C), using a non-exclusive logical OR, and should not be construed to mean “only one of A or B or C. The term “about” is defined to be within 10% of the referred value.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A thin shadow ring for a substrate processing system, the thin shadow ring comprising:
an annular body having an inner diameter and an outer diameter, wherein the inner diameter and the outer diameter define a cross-sectional width of the annular body between the inner diameter and the outer diameter; and
at least two tabs extending radially outward from the annular body, wherein
the cross-sectional width of the annular body between the inner diameter and the outer diameter is less than 1.0 inch.

2. The thin shadow ring of claim 1, wherein the cross-sectional width of the annular body between the inner diameter and the outer diameter is less than 0.5 inches.

3. The thin shadow ring of claim 1, wherein the cross-sectional width of the annular body between the inner diameter and the outer diameter is less than 0.25 inches.

4. The thin shadow ring of claim 1, wherein the at least two tabs includes at least three tabs extending radially outward from the annular body.

5. The thin shadow ring of claim 1, wherein at least one of the two tabs includes an opening extending through the tab.

6. The thin shadow ring of claim 1, wherein a lower surface of at least one of the two tabs includes a recess configured to receive a lift pin.

7. The thin shadow ring of claim 1, wherein an upper surface of the annular body is sloped.

8. A substrate support including the thin shadow ring of claim 1 and further comprising at least two lift pins configured to engage with the at least two tabs of the thin shadow ring to raise and lower the thin shadow ring.

9. The substrate support of claim 8, wherein at least one of the two tabs of the thin shadow ring extends over an outer edge of the substrate support.

10. The substrate support of claim 8, wherein the substrate support is configured to support a substrate having an outer diameter, and wherein an inner diameter of the annular body is less than the outer diameter of the substrate.

11. The substrate support of claim 8, wherein an upper surface of the substrate support defines a recess configured to receive a substrate, and wherein a portion of the annular body of the thin shadow ring overlaps the recess.

12. The thin shadow ring of claim 1, wherein an acute angle is defined at the inner diameter of the annular body between an upper surface of the annular body and a lower surface of the annular body, and wherein:
the upper surface and the lower surface form a sharp corner at an inner edge of the shadow ring;
the inner edge is rounded;
the inner edge has a radius between 0.0 and 0.025 inches;
the acute angle is between 1 and 35 degrees; or
a thickness of the inner edge is less than 0.01 inches.

13. A substrate support for a substrate processing system configured to perform deep-trench etching and shallow-trench etching, the substrate support comprising:
a recess defined in an upper surface of the substrate support, wherein the recess is configured to receive a substrate;
a shadow ring including an annular body having an inner diameter and an outer diameter, wherein the inner diameter and the outer diameter define a cross-sectional width of the annular body between the inner diameter and the outer diameter, and at least two tabs extending radially outward from the annular body over an outer edge of the substrate support, wherein the cross-sectional width of the annular body between the inner diameter and the outer diameter is less than 1.0 inches, and wherein the inner diameter of the annular body is less than an outer diameter of the recess; and
a lifting pin aligned with one of the at least two tabs of the shadow ring, wherein the lifting pin is configured to move the shadow ring between a lowered position and a raised position.

14. The substrate support of claim 13, wherein the cross-sectional width of the annular body between the inner diameter and the outer diameter is less than 0.5 inches.

15. The substrate support of claim 13, wherein the cross-sectional width of the annular body between the inner diameter and the outer diameter is less than 0.25 inches.

16. The substrate support of claim 13 wherein the shadow ring includes at least three tabs.

17. The substrate support of claim 13, wherein at least one of the two tabs includes an opening extending through the tab.

18. The substrate support of claim 13, wherein an upper surface of the annular body is sloped.

19. The substrate support of claim 13, wherein the inner diameter of the annular body is less than an outer diameter of the substrate.

20. A substrate processing system including the substrate support of claim 13, wherein the substrate processing system is configured to actuate the lifting pin to raise the shadow ring to the raised position during a shallow-trench etching process and lower the shadow ring to the lowered position during a deep-trench etching process.

21. The substrate support of claim 13, wherein an acute angle is defined at the inner diameter of the annular body between an upper surface of the annular body and a lower surface of the annular body, and wherein:
the upper surface and the lower surface form a sharp corner at an inner edge of the shadow ring;
the inner edge is rounded;
the inner edge has a radius between 0.0 and 0.025 inches;
the acute angle is between 1 and 35 degrees; or
a thickness of the inner edge is less than 0.01 inches.
